(19) United States
(12) Patent Application Publication
(10) Pub. No.: US 2015/0373842 A1
(43) Pub. Date: Dec. 24, 2015

(54) SUBSTRATE STRIP, SUBSTRATE PANEL, AND MANUFACTURING METHOD OF SUBSTRATE STRIP

(71) Applicant: SAMSUNG ELECTRO-MECHANICS CO., LTD., Suwon (KR)

(72) Inventors: Tae Hong MIN, Suwon (KR); Yi Hyun JUNG, Suwon (KR); Suk Hyeon CHO, Suwon (KR); Young Gwan KO, Suwon (KR)

(73) Assignee: SAMSUNG ELECTRO-MECHANICS CO., LTD., Suwon (KR)

(21) Appl. No.: 14/521,641

(22) Filed: Oct. 23, 2014

(30) Foreign Application Priority Data
Jun. 19, 2014 (KR) 10-2014-0074863

(51) Int. Cl. H05K 1/03; H05K 3/00

(52) U.S. Cl. CPC H05K 1/0306; H05K 3/0091; H05K 3/0055; H05K 2201/09036; H05K 2203/1377

(57) ABSTRACT

There are provided a substrate strip, a substrate panel, and a manufacturing method of a substrate strip. The substrate strip includes: a plurality of unit substrates including a glass core; and a glass core cover part disclosed on a side surface of the substrate strip on which the glass core is exposed.

### CROSS-REFERENCE TO RELATED APPLICATION

This application claims the benefit of Korean Patent Application No. 10-2014-0074863 filed on Jun. 19, 2014, with the Korean Intellectual Property Office, the disclosure of which is incorporated herein by reference.

### BACKGROUND

The present disclosure relates to a substrate strip, a substrate panel, and a manufacturing method of a substrate strip.

In accordance with the gradual thinning of printed circuit boards, deformation such as warpage, torsion, and the like, occurring in such thinned printed circuit boards at the time of manufacturing the printed circuit board has increased. In order to prevent the deformation of printed circuit boards, a glass core structure in which a glass plate is embedded in a core part of the printed circuit board has been suggested.

### RELATED ART DOCUMENT

(Patent Document 1) Korean Patent Laid-Open Publication No. 2012-0095426

### SUMMARY

An exemplary embodiment in the present disclosure may provide a substrate strip, a substrate panel, and a manufacturing method of a substrate strip that are capable of preventing a defect in which a substrate is widened due to exposure of a glass core and significantly decreasing occurrence of cracking in the glass core.

According to an exemplary embodiment in the present disclosure, a substrate strip in which a glass core cover part is disposed on a side surface on which a glass core is exposed may be provided.

The glass core cover parts may be further disposed on a side surface of a plurality of unit substrates included in the substrate strip.

The glass core cover parts may be formed by applying a protective material to an exposed surface of the glass core of the substrate strip or may be formed by forming trenches in a side surface of the substrate strip in a substrate panel including a plurality of substrate strips and filling the trenches with protective materials.

### BRIEF DESCRIPTION OF DRAWINGS

The above and other aspects, features and other advantages in the present disclosure will be more clearly understood from the following detailed description taken in conjunction with the accompanying drawings, in which:

FIG. 1 is a perspective view of a substrate strip according to an exemplary embodiment in the present disclosure;

FIG. 2 is a cross-sectional view taken along line I-I′ of part A of FIG. 1;

FIG. 3 is a cross-sectional view taken along line I-I′ of part A of FIG. 1 according to another exemplary embodiment in the present disclosure;

FIG. 4 is a cross-sectional view taken along line I-I′ of part A of FIG. 1 according to another exemplary embodiment in the present disclosure;

FIG. 5 is a cross-sectional view taken along line II-II′ of part A of FIG. 1;

FIG. 6 is an enlarged view of part B of FIG. 1;

FIGS. 7A and 7B are cross-sectional views taken along line III-III′ of FIG. 6;

FIG. 8 is a perspective view of a substrate panel according to an exemplary embodiment in the present disclosure;

FIG. 9 is an enlarged view of part C of FIG. 8;

FIG. 10 is a cross-sectional view taken along line IV-IV′ of part C of FIG. 8;

FIG. 11 is an enlarged view of part C of FIG. 8 according to another exemplary embodiment in the present disclosure;

FIG. 12 is a flow chart illustrating a manufacturing method of a substrate strip according to an exemplary embodiment in the present disclosure; and

FIGS. 13A and 13B are views illustrating a process of forming a glass core cover part according to an exemplary embodiment in the present disclosure.

### DETAILED DESCRIPTION

Hereinafter, embodiments in the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Substrate Strip

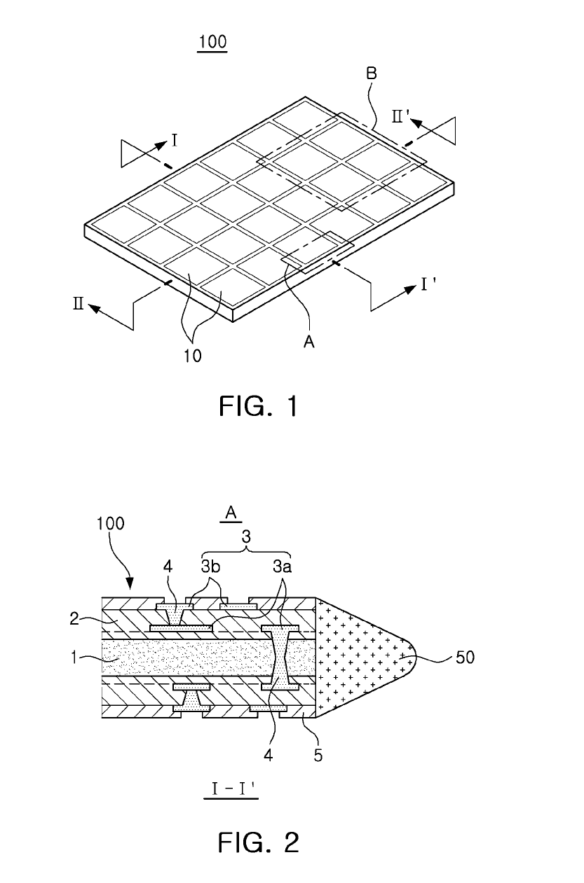

FIG. 1 is a perspective view of a substrate strip according to an exemplary embodiment in the present disclosure.

Referring to FIG. 1, a substrate strip 100 according to an exemplary embodiment in the present disclosure may include a plurality of unit substrates 10.

The unit substrate 10 may have a semiconductor chip (not shown) mounted on one surface thereof and a main board (not shown) connected to the other surface thereof.

Arrangements and structures of the unit substrates 100 disposed in the substrate strip 100 are not limited to the arrangements and structures illustrated in FIG. 1, but may be variously set depending on the intention of a designer.

FIG. 2 is a cross-sectional view taken along line I-I′ of part A of FIG. 1.

Referring to FIG. 2, the substrate strip 100 may include a glass core 1.

The glass core 1 may have an insulating layer 2 and a conductor pattern 3 disposed on the one surface thereof.

The insulating layer 2 may be formed of a thermosetting resin such as an epoxy resin, a thermoplastic resin such as polyimide, a resin formed by impregnating the thermosetting resin or the thermoplastic resin with a reinforcing material such as a glass fiber, an inorganic filler, or the like.

First and second conductor patterns 3a and 3b may be connected to each other by a via 4 penetrating through the insulating layer 2.

The glass core 1 may also have an insulating layer 2 and a conductor pattern 3 disposed on the other surface thereof opposing the one surface thereof.

The first conductor patterns 3a disposed on both surfaces of the glass core 1, respectively, may be connected to each other by a via 4 penetrating through the glass core 1.

The substrate strip 100 may have a solder resist 5 formed on a surface thereof so that a conductor pattern for an external terminal connection pad among the second conductor patterns 3b, the outermost conductor patterns, is exposed.

The glass core 1 may contain glass, an amorphous solid.

An example of a glass material that may be used in an exemplary embodiment in the present disclosure may include pure silicon dioxide (SiO₂ in an amount of approximately 1000), soda lime glass, borosilicate glass, alumino-silicate glass, and the like. However, an example of a glass material that may be used in an exemplary embodiment is not limited to the above-mentioned silicon-based glass compositions. That is, fluoride glass, phosphate glass, chalcogenide glass, or the like, which is an alternative glass material, may be used.

In addition, the glass core may further contain other additives in order to form glass having specific physical properties. These additives may include magnesium, calcium, manganese, aluminum, lead, boron, iron, chromium, potassium, sulfur, and antimony, as well as carbonates and/or oxides of these elements and other elements as well as calcium carbonate (for example, lime) and sodium carbonate (for example, soda).

Here, the glass core 1 containing the glass may be effective in preventing a warpage phenomenon occurring at the time of manufacturing the substrate. However, due to characteristics of the glass, there is a high likelihood that cracking will occur in the glass core 1 during cutting the substrate in a manufacturing process thereof, and a defect in which the substrate is widened in the case that only a slight impact is applied to the glass core 1 that is exposed may occur.

Therefore, in an exemplary embodiment, a glass core cover part 50 is disposed on a side surface of the substrate strip 100 on which the glass core 1 is exposed, whereby the glass core 1 may be protected without being externally exposed, and the defect in which the substrate is widened and the occurrence of cracking in the glass core may be prevented.

The glass core cover part 50 may be formed of any material able to prevent the glass core 1 from being externally exposed to prevent the defect in which the substrate is widened, for example, a thermosetting resin such as an epoxy resin, a thermoplastic resin such as polyimide, a resin formed by adding an inorganic filler, a metal, or the like, to the thermosetting resin and the thermoplastic resin, or the like.

The glass core cover part 50 according to an exemplary embodiment in the present disclosure may be formed on entirety of a side surface of the substrate strip 100 on which the glass core 1 is exposed.

The glass core cover part 50 may be formed on entirety of a side surface of the substrate strip 100 on which the glass core 1 is exposed by applying a protective material to an exposed surface of the glass core 1 of the substrate strip 100.

Here, the glass core cover part 50 may be formed in a protruded manner as illustrated in FIG. 2.

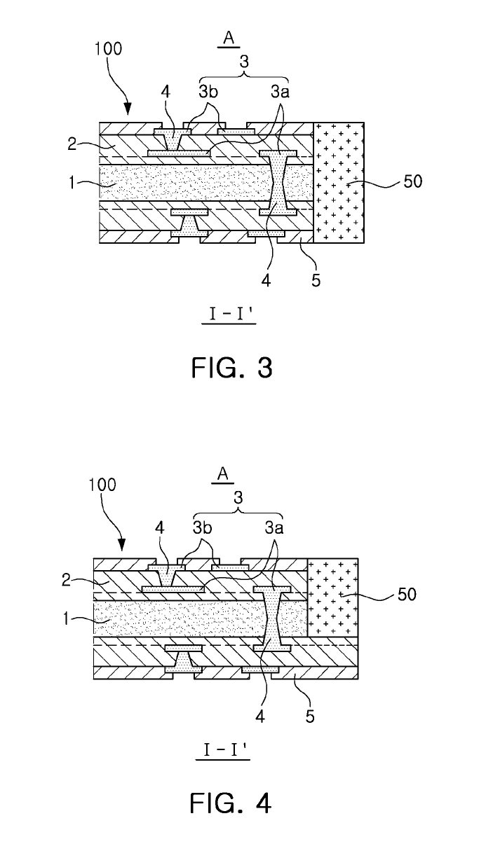

FIG. 3 is a cross-sectional view taken along line I-I′ of part A of FIG. 1 according to another exemplary embodiment in the present disclosure.

Referring to FIG. 3, the glass core cover part 50 may be formed in a flat shape rather than in the protrusion shape.

Similar to the case of FIG. 2, the glass core cover part 50 having the flat shape may be formed on entirety of a side surface of the substrate strip 100 on which the glass core 1 is exposed by applying a protective material to an exposed surface of the glass core 1 of the substrate strip 100.

FIG. 4 is a cross-sectional view taken along line I-I′ of part A of FIG. 1 according to another exemplary embodiment in the present disclosure.

Referring to FIG. 4, the glass core cover part 50 may be formed from an upper portion of a side surface of the substrate strip 100 on which the glass core 1 is exposed, in a thickness direction.

Here, the glass core cover part 50 may be formed from the upper portion of the substrate strip 100 in the thickness direction to a lower surface of the glass core 1.

The glass core cover part 50 formed in only a partial region in the thickness direction as described above may be formed by forming a trench in a side surface of the substrate strip 100 in a substrate panel including a plurality of substrate strips 100 and then filling the trench with a protective material.

Even though the glass core cover part 50 is not formed to a lower portion of the substrate strip 100 in the thickness direction, when the glass core cover part 50 is formed to the lower surface of the glass core 1, the glass core 1 is not exposed, such that the defect in which the substrate is widened may be effectively prevented.

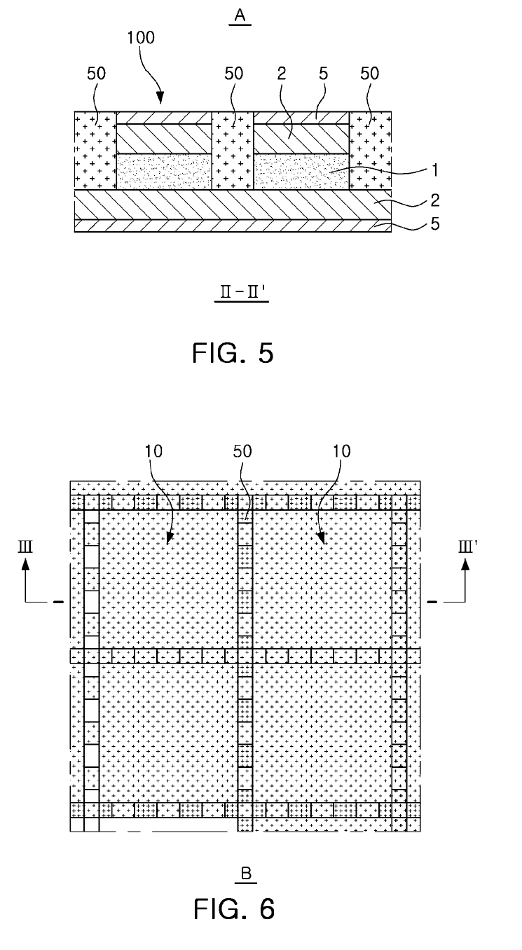

FIG. 5 is a cross-sectional view taken along line II-II′ of part A of FIG. 1 according to another exemplary embodiment in the present disclosure.

Referring to FIG. 5, the glass core cover parts 50 may be non-continuously formed on a side surface of the substrate strip 100 on which the glass core 1 is exposed so as to be spaced apart from each other by predetermined intervals.

The glass core cover parts 50 non-continuously formed on aside surface of the substrate strip 100 as described above may be formed by non-continuously forming trenches in a side surface of the substrate strip 100 so as to be spaced apart from each other by predetermined intervals in a substrate panel including a plurality of substrate strips 100 and then filling the trenches with protective materials.

When the glass core cover parts 50 are non-continuously formed as illustrated in FIG. 5, even though the glass core 1 is partially exposed, it may be advantageous in supporting an entire substrate panel, and in preventing the defect in which the substrate is widened may be prevented only by non-continuously forming the glass core cover parts 50.

Although the case in which the glass core cover parts 50 are non-continuously formed from the upper portion of the substrate strip 100 in the thickness direction to the lower surface of the glass core 1 has been illustrated in FIG. 5, the present disclosure is not limited thereto. That is, the glass core parts 50 non-continuously formed may penetrate through the substrate strip 100 in the thickness direction (not shown).

FIG. 6 is an enlarged view of part B of FIG. 1.

Referring to FIG. 6, the glass core cover parts 50 may be further disposed on a side surface of the unit substrate 10 included in the substrate strip 100.

The glass core cover parts 50 are disposed on a side surface of the unit substrate 10, whereby the glass core 1 may be protected without being externally exposed and the defect in which the substrate is widened and the occurrence of cracking may be prevented, in the unit substrates 10 that are cut.

The glass core cover parts 50 disposed on a side surface of the unit substrate 10 may be non-continuously formed on a side surface of the unit substrate 10 so as to be spaced apart from each other by predetermined intervals.

In order to support the substrate strip 100 including the plurality of unit substrates 10, the glass core cover parts 50 disposed on a side surface of the unit substrate 10 may be non-continuously formed.

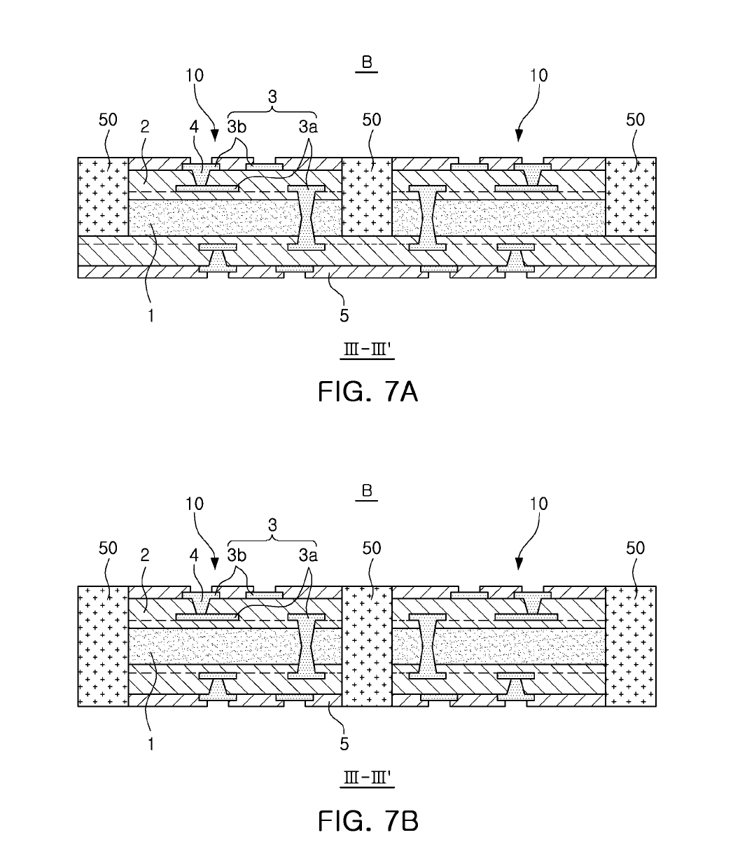

FIGS. 7A and 7B are cross-sectional views taken along line III-III′ of FIG. 6.

Referring to FIG. 7A, the glass core cover parts 50 disposed on a side surface of the unit substrate 10 may have a trench shape in which they do not penetrate through the unit substrate 10 in the thickness direction.

The glass core cover part 50 may be formed from an upper portion of the unit substrate 10 in the thickness direction to the lower surface of the glass core 1.

The glass core cover parts 50 disposed on a side surface of the unit substrate 10 and having the trench shape may be formed by forming trenches in a side surface of the unit substrate 10 and then filling the trenches with protective materials.

Referring to FIG. 7B, a cross-sectional view taken along line III-III′ of FIG. 6 according to another exemplary embodiment in the present disclosure, the glass core cover parts 50 non-continuously formed and disposed on a side surface of the unit substrate 10 may penetrate through the unit substrate 10 in the thickness direction.

### Substrate Panel

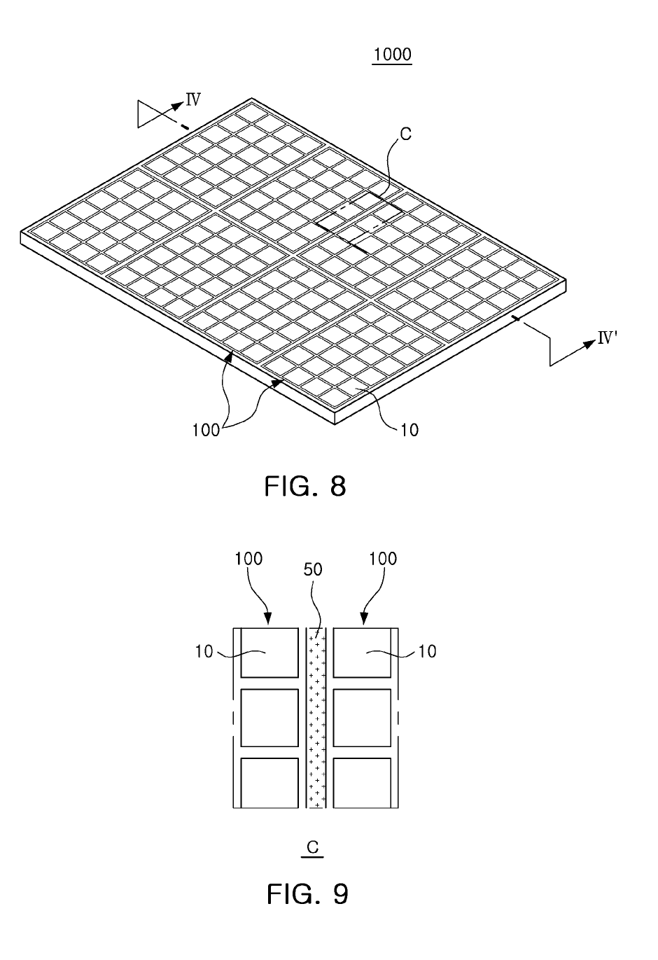

FIG. 8 is a perspective view of a substrate panel according to an exemplary embodiment in the present disclosure.

Referring to FIG. 8, a substrate panel 1000 according to an exemplary embodiment in the present disclosure may include a plurality of substrate strips 100.

Arrangements and structures of the substrate strips 100 disposed in the substrate panel 1000 are not limited to the arrangements and structures illustrated in FIG. 8, but may be variously set depending on the intention of a designer.

The substrate strip 100 disposed in the substrate panel 1000 may include the glass core 1. There is a high likelihood that cracking will occur in the glass core 1 during cutting the substrate in a manufacturing process of the substrate, and a defect in which the substrate is widened with only slight impact applied to the glass core 1 that is exposed occurs, due to characteristics of the glass.

Therefore, in the substrate panel 1000 according to an exemplary embodiment in the present disclosure, the glass core cover part 50 is disposed on a side surface of the substrate strip 100, whereby the glass core 1 may be protected without being externally exposed, and the defect in which substrate is widened and the occurrence of cracking in the glass core may be prevented.

FIG. 9 is an enlarged view of part C of FIG. 8.

Referring to FIG. 9, the glass core cover part 50 may be formed along a side surface of the substrate strip 100 included in the substrate panel 1000.

The glass core cover part 50 may be formed by forming a trench in a side surface of the substrate strip 100 in the substrate panel 1000 and then filling the trench with a protective material.

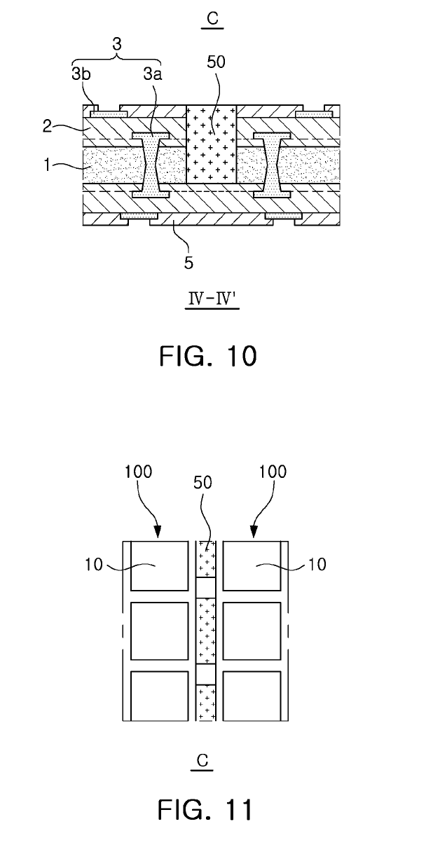

FIG. 10 is a cross-sectional view taken along line IV-IV′ of part C of FIG. 8.

Referring to FIG. 10, the glass core cover part 50 may have a trench shape in which it does not penetrate through the substrate strip 100 in the thickness direction.

Here, the glass core cover part 50 having the trench shape may be formed from the upper portion of the substrate strip 100 in the thickness direction to the lower surface of the glass core 1.

FIG. 11 is an enlarged view of part C of FIG. 8 according to another exemplary embodiment in the present disclosure.

Referring to FIG. 11, the glass core cover parts 50 may be non-continuously formed on a side surface of the substrate strip 100 so as to be spaced apart from each other by predetermined intervals.

The glass core cover parts 50 non-continuously formed on aside surface of the substrate strip 100 as described above may be formed by non-continuously forming trenches in a side surface of the substrate strip 100 so as to be spaced apart from each other by predetermined intervals in the substrate panel 1000 and then filling the trenches with protective materials.

The glass core cover parts 50 non-continuously formed as described above may be formed from the upper portion of the substrate strip 100 in the thickness direction to the lower surface of the glass core 1, but are not limited thereto. That is, the glass core cover parts 50 may penetrate through the substrate strip 100 in the thickness direction.

### Manufacturing Method of Substrate Strip

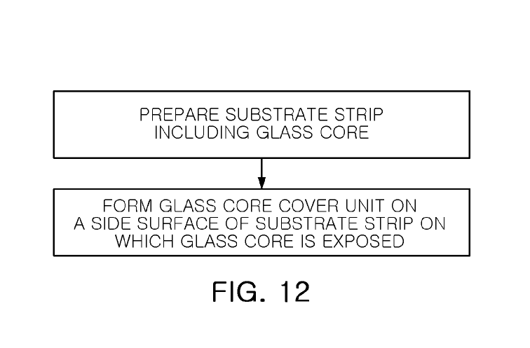

FIG. 12 is a flow chart illustrating a manufacturing method of a substrate strip according to an exemplary embodiment in the present disclosure.

Referring to FIG. 12, the substrate strip 100 including the glass core 1 may be prepared.

The substrate strip 100 including the glass core 1 may be manufactured by forming the via 4 penetrating through the glass core 1 and forming the insulating layers 2 and the conductor patterns 3 on both surfaces of the glass core.

Next, the glass core cover part 50 may be formed on a side surface of the substrate strip 100 on which the glass core 1 is exposed.

According to an exemplary embodiment in the present disclosure, the glass core cover part 50 may be formed by applying the protective material onto the exposed surface of the glass core 1 of the cut substrate strip 100.

The glass core cover part 50 may be formed on the entirety of a side surface of the substrate strip 100 on which the glass core 1 is exposed by applying the protective material onto the exposed surface of the glass core 1 of the cut substrate strip 100.

The glass core cover part 50 formed as described above may have a protrusion shape or a flat shape.

According to another exemplary embodiment in the present disclosure, the glass core cover parts 50 may be formed before the plurality of substrate strips 100 are cut from the substrate panel.

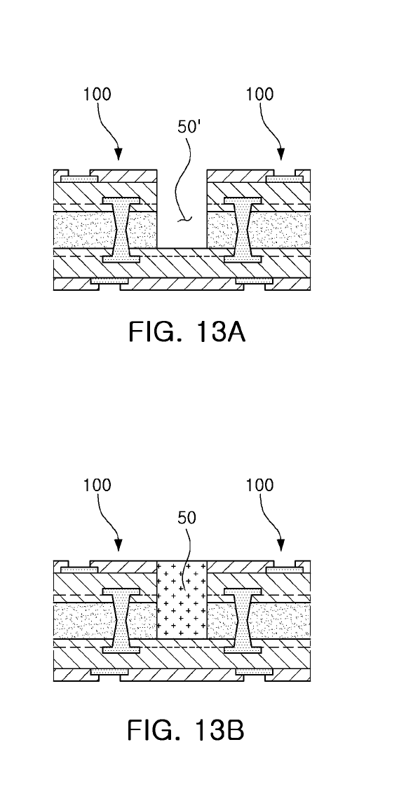

FIGS. 13A and 13B are views illustrating a process of forming a glass core cover part according to an exemplary embodiment in the present disclosure.

Referring to FIG. 13A, in the substrate panel 1000 including the plurality of substrate strips 100, trenches 50′ may be formed along a side surface of the substrate strip 100.

Here, the trenches 50′ may be formed from the upper portion of the substrate strip 100 in the thickness direction to a depth of the lower surface of the glass core 1.

In addition, the trenches 50′ may be non-continuously formed on a side surface of the substrate strip 100 so as to be spaced apart from each other by predetermined intervals.

Referring to FIG. 13B, the glass core cover parts 50 may be formed by filling the trenches 50′ with protective materials.

Meanwhile, the glass core cover parts 50 may be formed by non-continuously forming penetration holes along a side surface of the substrate strip 100 so as to be spaced apart from each other by predetermined intervals in the substrate panel 1000 including the plurality of substrate strips 100 and then filling protective materials in the penetration holes (not shown).

In addition, according to an exemplary embodiment in the present disclosure, the glass core cover parts 50 may also be formed on aside surface of the plurality of unit substrates 10 included in the substrate strip 100.

Since other features are the same as those of the substrate strip according to an exemplary embodiment in the present disclosure described above, a description thereof will be omitted.

As set forth above, according to exemplary embodiments in the present disclosure, the defect in which the substrate is widened due to the exposure of the glass core may be prevented and the occurrence of cracking in the glass core may be significantly decreased.

While exemplary embodiments have been shown and described above, it will be apparent to those skilled in the art that modifications and variations could be made without departing from the scope of the invention as defined by the appended claims.

What is claimed is:

1. A substrate strip comprising:
a plurality of unit substrates including a glass core; and
a glass core cover part disposed on a side surface of the substrate strip on which the glass core is exposed.

2. The substrate strip of claim 1, wherein the glass core cover part is formed on entirety of a side surface of the substrate strip on which the glass core is exposed.

3. The substrate strip of claim 1, wherein the glass core cover part is formed from an upper portion of a side surface of the substrate strip on which the glass core is exposed to a partial region in a thickness direction.

4. The substrate strip of claim 1, wherein the glass core cover parts are non-continuously disposed on a side surface of the substrate strip on which the glass core is exposed so as to be spaced apart from each other by predetermined intervals.

5. The substrate strip of claim 1, wherein the glass core cover parts are further disposed on a side surface of the unit substrate.

6. The substrate strip of claim 5, wherein the glass core cover parts disposed on a side surface of the unit substrate are non-continuously disposed on a side surface of the unit substrate so as to be spaced apart from each other by predetermined intervals.

7. The substrate strip of claim 5, wherein the glass core cover parts disposed on a side surface of the unit substrate have a trench shape in which the glass core cover parts do not penetrate through the unit substrate in a thickness direction.

8. The substrate strip of claim 5, wherein the glass core cover parts disposed on a side surface of the unit substrate penetrate through the unit substrate in a thickness direction.

9. A substrate panel comprising:
a plurality of unit substrate strips including a glass core; and
a glass core cover part disposed on a side surface of the unit substrate strip.

10. The substrate panel of claim 9, wherein the glass core cover part has a trench shape in which the glass core cover part does not penetrate through the unit substrate strip in a thickness direction.

11. The substrate panel of claim 10, wherein the glass core cover part having the trench shape is formed from an upper portion of the unit substrate strip in the thickness direction to a lower surface of the glass core.

12. The substrate panel of claim 9, wherein the glass core cover parts are non-continuously formed on a side surface of the unit substrate strip so as to be spaced apart from each other by predetermined intervals.

13. The substrate panel of claim 12, wherein the glass core cover parts non-continuously formed penetrate through the unit substrate strip in a thickness direction.

14. A manufacturing method of a substrate strip including a plurality of unit substrates, comprising:
preparing the substrate strip including a glass core; and
forming a glass core cover part on a side surface of the substrate strip on which the glass core is exposed.

15. The manufacturing method of a substrate strip of claim 14, wherein in the forming of the glass core cover part, the glass core cover part is formed by applying a protective material to an exposed surface of the glass core of the substrate strip.

16. The manufacturing method of a substrate strip of claim 14, wherein the forming of the glass core cover part includes:
forming trenches in aside surface of the substrate strip in a substrate panel including a plurality of substrate strips; and
filling the trenches with protective materials to form the glass core cover parts.

17. The manufacturing method of a substrate strip of claim 16, wherein the trenches are formed to a depth of a lower surface of the glass core.

18. The manufacturing method of a substrate strip of claim 16, wherein the trenches are non-continuously formed along a side surface of the substrate strip so as to be spaced apart from each other by predetermined intervals.

19. The manufacturing method of a substrate strip of claim 14, wherein the forming of the glass core cover part includes:
non-continuously forming penetration holes along a side surface of the substrate strip so as to be spaced apart from each other by predetermined intervals in a substrate panel including a plurality of substrate strips; and
filling protective materials in the penetration holes to form the glass core cover parts.

20. The manufacturing method of a substrate strip of claim 14, further comprising forming the glass core cover parts on a side surface of the plurality of unit substrates included in the substrate strip.
